(19) United States
(12) Patent Application Publication
(10) Pub. No.: US 2012/0028430 A1
(43) Pub. Date: Feb. 2, 2012

(54) METHOD AND STRUCTURE TO IMPROVE FORMATION OF SILICIDE

(75) Inventors: Ming Cai, Hopewell Junction, NY (US); Ahmet S. Ozcan, Pleasantville, NY (US); Stefan Zollner, Hopewell Junction, NY (US)

(73) Assignee: INTERNATIONAL BUSINESS MACHINES CORPORATION, Armonk, NY (US)

(21) Appl. No.: 12/843,998

(22) Filed: Jul. 27, 2010

(51) Int. Cl. H01L 21/336; H01L 21/28

(52) U.S. Cl. 438/299; 438/592; 257/E21.19; 257/E21.438

(57) ABSTRACT

A method begins with a structure having: a gate insulator on a silicon substrate between a gate conductor and a channel region within the substrate; insulating sidewall spacers on sidewalls of the gate conductor; and source and drain regions within the substrate adjacent the channel region. To silicide the gate and source and drain regions, the method deposits a metallic material over the substrate, the gate conductor, and the sidewalls, and performs a first heating process to change the metallic material into a metal-rich silicide at locations where the metallic material contacts silicon. The method removes the sidewall spacers, and performs a second heating process to change the metal-rich silicide into silicide having a lower metallic concentration than the metal-rich silicide. The silicide thus formed avoids being damaged by the spacer removal process.

### BACKGROUND

1. Field of the Invention

The embodiments of the invention generally relate to integrated circuit structures and, more specifically, to integrated circuit transistor structures that utilize silicides to lower resistance of the structures within the transistor.

2. Description of the Related Art

Integrated circuits are often formed with transistor structures. One common transistor structure is a metal oxide semiconductor field effect transistor (MOSFET). Such a transistor is formed on a silicon substrate and includes a semiconductor region (channel region) which is made either conductive or nonconductive depending upon the voltage within an adjacent gate conductor. The channel region forms an electrical connection between conductive source and drain regions of the substrate.

One advance that assists in reducing the resistance of the transistor is the formation of silicide on the source and drain, and sometimes on the gate conductor. Such silicide, is formed by depositing a metal on silicon surfaces and then performing an annealing process which converts the metal into silicide. However, such silicide structures can be damaged by subsequent processing, such as reactive ion etching (RIE) processing that removes sidewall spacers that are sometimes formed adjacent the gate conductor.

### SUMMARY

In view of the foregoing, one embodiment disclosed herein is a method that begins with a structure having: a gate insulator on a silicon substrate between a gate conductor and a channel region within the substrate; insulating sidewall spacers on sidewalls of the gate conductor; and source and drain regions within the substrate adjacent the channel region. To silicide the gate and source and drain regions, the method deposits a metallic material over the substrate, the gate conductor, and the sidewalls, and performs a first heating process to change the metallic material into a metal-rich silicide at locations where the metallic material contacts silicon. The method removes the sidewall spacers, and performs a second heating process to change the metal-rich silicide into silicide having a lower metallic concentration than the metal-rich silicide. The silicide thus formed avoids being damaged by the spacer removal process.

Another embodiment forms at least one channel region within a silicon substrate, forms at least one gate insulator on the substrate adjacent the channel region, forms at least one gate conductor on the gate insulator to position the gate conductor such that the gate insulator is between the gate conductor and the channel region, forms insulating sidewall spacers on sidewalls of the gate conductor, and forms source and drain regions within the substrate adjacent the channel region. Again, to silicide the gate and source and drain regions, the method deposits a metallic material over the substrate, the gate conductor, and the sidewalls, and performs a first heating process to change the metallic material into a metal-rich silicide at locations where the metallic material contacts silicon. The method removes the sidewall spacers, and performs a second heating process to change the metal-rich silicide into silicide having a lower metallic concentration than the metal-rich silicide.

Another method of forming a transistor structure provides a silicon substrate and implants an impurity into a region of the substrate to form at least one channel region within the substrate. The method patterns an insulator on the substrate to form at least one gate insulator adjacent the channel region and patterns a conductor on the insulator to form at least one gate conductor on the insulator and to position the gate conductor such that the gate insulator is between the gate conductor and the channel region. The method forms insulating sidewall spacers on sidewalls of the gate conductor, and implants additional impurity into the substrate around the gate conductor and the sidewalls to form source and drain regions within the substrate adjacent the channel region.

To silicide the gate and source and drain regions, the method again deposits a metallic material over the substrate, the gate conductor, and the sidewalls, and performs a first heating process to change the metallic material into a metal-rich silicide at locations where the metallic material contacts silicon. The method removes the sidewall spacers, and performs a second heating process to change the metal-rich silicide into silicide having a lower metallic concentration than the metal-rich silicide.

An additional method herein forms a transistor structure by also providing a silicon substrate, and implanting an impurity into a region of the substrate to form at least one semiconductor channel region within the substrate. This embodiment patterns an insulator on the substrate to form at least one gate insulator adjacent the channel region, and patterns a polysilicon conductor on the insulator to form at least one gate conductor on the insulator and to position the gate conductor such that the gate insulator is between the gate conductor and the channel region. The method forms insulating sidewall spacers on sidewalls of the gate conductor, and implants additional impurity into the substrate around the gate conductor and the sidewalls to form conductive source and drain regions within the substrate adjacent the channel region.

This method similarly deposits a metallic material over the substrate, the gate conductor, and the sidewalls, and performs a first rapid thermal annealing process to change the metallic material into a metal-rich silicide at locations where the metallic material contacts silicon. The method performs a selective reactive ion etching process to remove the sidewall spacers. The selected reactive ion etching (RIE) process may produce some damage within the metal-rich silicide. However, the method also performs a second rapid thermal annealing process to change the metal-rich silicide into silicide having a lower metallic concentration than the metal-rich silicide, and this silicide that is formed does not suffer from such RIE damage.

### BRIEF DESCRIPTION OF THE DRAWINGS

The embodiments of the invention will be better understood from the following detailed description with reference to the drawings, which are not necessarily drawing to scale and in which:

FIG. 1 is cross-sectional schematic diagram of an integrated circuit structure according to embodiments herein;

FIG. 2 is cross-sectional schematic diagram of an integrated circuit structure according to embodiments herein;

FIG. 3 is cross-sectional schematic diagram of an integrated circuit structure according to embodiments herein;

FIG. 4 is cross-sectional schematic diagram of an integrated circuit structure according to embodiments herein;

FIG. 5 is cross-sectional schematic diagram of an integrated circuit structure according to embodiments herein;

FIG. 6 is cross-sectional schematic diagram of an integrated circuit structure according to embodiments herein;

FIG. 7 is cross-sectional schematic diagram of an integrated circuit structure according to embodiments herein; and

FIG. 8 is a flow diagram illustrating method embodiments herein.

### DETAILED DESCRIPTION

As mentioned above, silicides are often used to reduce the resistance of silicon base transistors. However, such silicide structures can be damaged by subsequent processing, such as reactive ion etching (RIE) processing.

Post silicide spacer removal has been employed in technologies that utilize stress liners, in order to increase stress and enhance performance. Typically, dry etch (i.e., RIE) is used to remove oxide and nitride spacers. The RIE process is conventionally done after silicidation is complete. The problem with this approach is erosion of the silicide surface, which increases sheet resistance and contact resistance. Missing silicide defects can also be created by the RIE process which causes opens and yield loss.

Typically, dry etch (i.e., RIE) is used to remove oxide and nitride spacers. Even though the RIE chemistry can be adjusted to achieve better selectivity to the silicide, the physical bombardment component can always damage the silicide surface. Heavy elements at the silicide surface can withstand RIE damage and protect the surface.

In view of these issues, the embodiments herein split the silicidation process into two parts, and remove the sidewall spacers in the middle of the silicidation process. Therefore, the embodiments herein perform spacer removal RIE after a metal-rich silicide formation (after a first low temperature rapid thermal annealing (RTA)) and a first selective etching process. The first RTA is typically done at a low enough temperature that only forms a metal-rich silicide (e.g., Ni₂Si). The selective etch removes all the unreacted metal from spacers and other insulators.

Therefore, the embodiments herein first perform a preclean and alloy deposition. Next, a low temperature anneal (e.g., 240° C. to 340° C.) is performed to form the metal rich silicide. A selective etch removes any unreacted metal and this is followed by the RIE spacer removal. Then, the silicidation process is completed with a higher temperature formation anneal (e.g., 420° C. to 500° C.) to form metal-Si phase, that also heals any residual RIE damage.

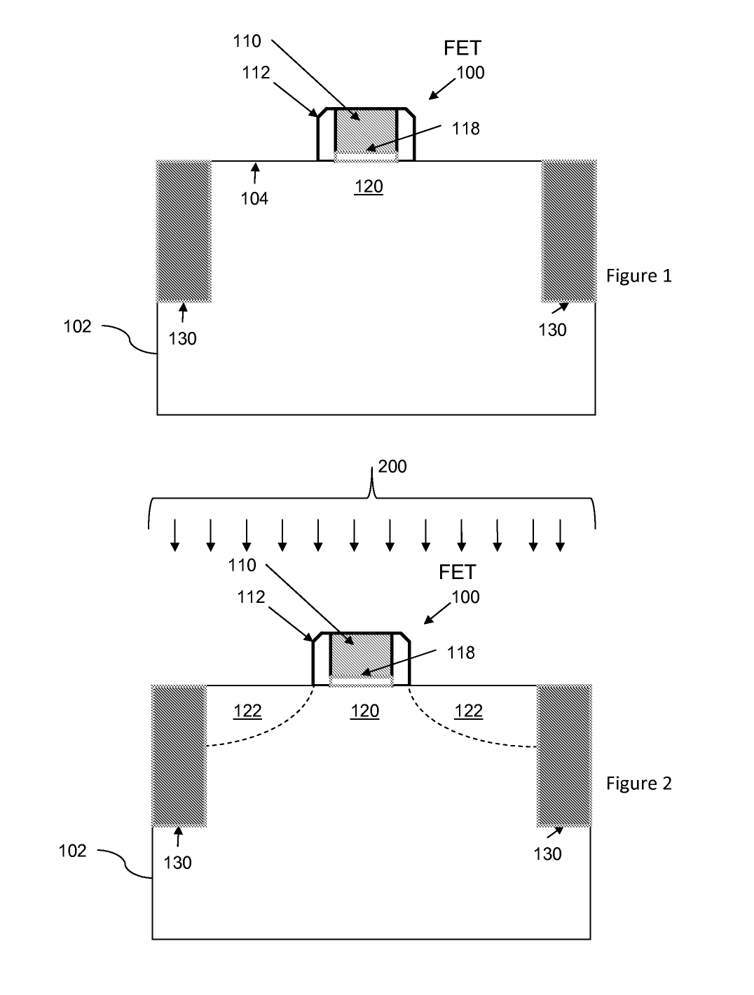

One example of the embodiments herein is shown in FIGS. 1-7. FIGS. 1-7 illustrate, in cross-sectional schematic view, the formation of an integrated circuit structure 100 that includes a substrate 102. Generally, transistor structures are formed by depositing or implanting impurities into a substrate 102 to form at least one semiconductor channel region 120, bordered by shallow trench isolation regions 130 below the top (upper) surface 104 of the substrate 102, as shown in FIG. 1.

The substrate 102 can comprise any material appropriate for the given purpose (whether now known or developed in the future) and can comprise, for example, Si, SiC, SiGe, SiGeC, Ge alloys, GaAs, InAs, TnP, other III-V or II-VI compound semiconductors, or organic semiconductor structures etc. The impurities can comprises any negative-type impurity (N-type impurity, e.g., phosphorus (P), arsenic (As), antimony (Sb) etc.) or any positive-type impurity (P-type impurity, e.g., boron, indium, etc.). The channel region 120 is doped differently depending upon whether the transistor will be a positive-type or a negative-type transistor.

The shallow trench isolation (STI) structures 130 are well-known to those ordinarily skilled in the art and are generally formed by patterning openings/trenches within the substrate and growing or filling the openings with a highly insulating material. /

The method forms a gate dielectric 118 on the upper surface of the substrate 102 over the semiconductor channel region 120 and patterns a gate conductor 110 on the gate dielectric 118 over the semiconductor channel region 120, as shown in FIG. 1. The dielectrics (insulators) mentioned herein can, for example, be grown from either a dry oxygen ambient or steam and then patterned. Alternatively, the dielectrics herein may be formed from any of the many candidate high dielectric constant (high-k) materials, including but not limited to silicon nitride, silicon oxynitride, a gate dielectric stack of SiO₂ and Si₃N₄, and metal oxides like tantalum oxide. The thickness of dielectrics herein may vary contingent upon the required device performance.

The conductors mentioned herein (such as the gate conductor 110) can be formed of any conductive material, such as polycrystalline silicon (polysilicon), amorphous silicon, a combination of amorphous silicon and polysilicon, and polysilicon-germanium, rendered conductive by the presence of a suitable dopant. Alternatively, the conductors herein may be one or more metals, such as tungsten, hafnium, tantalum, molybdenum, titanium, or nickel, or a metal silicide, and may be deposited using physical vapor deposition, chemical vapor deposition, or any other technique known in the art.

As shown in FIG. 1, the gate conductor 110 has sidewalls. The embodiments herein form sidewall spacers 112 on the sidewalls of the gate conductor 110. Sidewall spacers are structures that are well-known to those ordinarily skilled in the art and are generally formed by depositing or growing a conformal insulating layer (such as any of the insulators mentioned above) and then performing a directional etching process (anisotropic) that etches material from horizontal surfaces at a greater rate than its removes material from vertical surfaces, thereby leaving insulating material along the vertical sidewalls of structures. This material left on the vertical sidewalls is referred to as sidewall spacers.

In FIG. 2, an impurity 200 is implanted to form the source and drain implants 122 adjacent the top surface of the substrate. Thus, using the sidewall spacers 112 as an alignment feature, any of the impurities mentioned above are implanted into the substrate to form the source and drain regions 114. The channel region 120 is positioned between the source and drain regions 122. The impurity of the source and drain regions 122 has an opposite polarity (negative (N-type) or positive (P-type) with respect to the impurity in the channel regions 120.

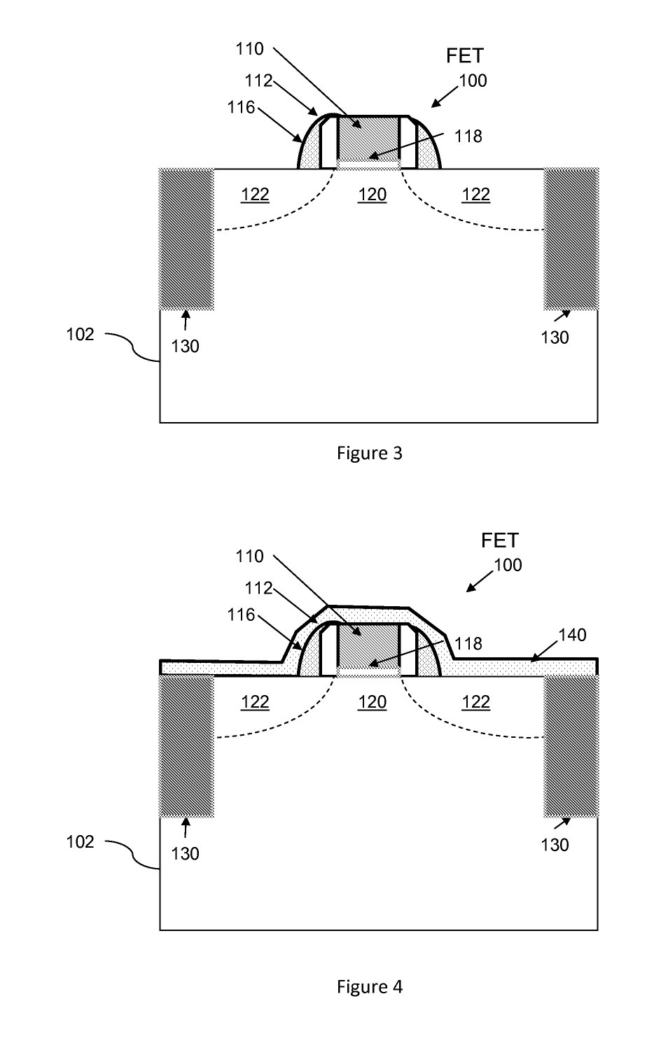

The implantation processes mentioned herein can take any appropriate form (whether now known or developed in the future) and can comprise, for example, ion implantation, etc. Also see U.S. Pat. No. 6,815,317 (incorporated herein by reference) for a full discussion of implantation techniques. Again, different transistors will utilizes different polarity dopants depending upon the polarity of the transistor for the source and drain regions. As shown in FIG. 3, additional spacers 116 can be formed on the original spacers 112 and angled halo implants can be performed, if desired.

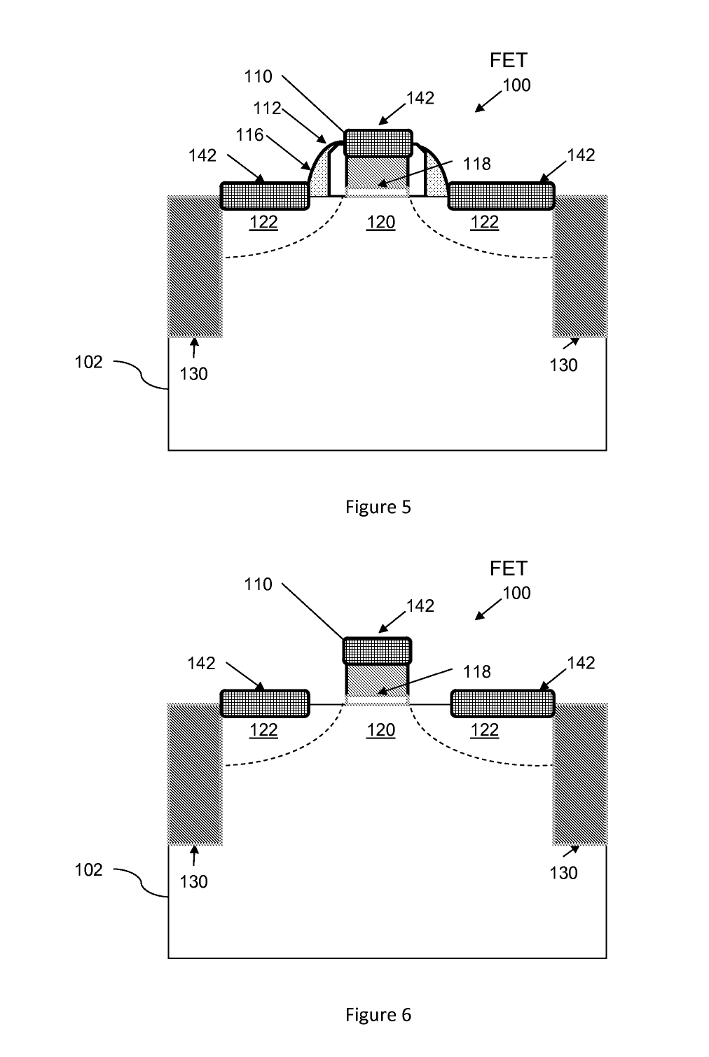

As shown in FIG. 4, the exposed portions of the silicon are then silicided. More specifically, a pre-cleaning operation is performed and then a metallic material 140 (e.g., a metallic alloy of nickel, lead) is deposited over the substrate, the gate conductor, and the sidewalls. As shown in FIG. 5, with the metallic material 140 in place, the method performs a first rapid thermal annealing process to change the metallic material into a metal-rich silicide 142 at locations where the metallic material 140 contacts silicon.

The method removes un-reacted portions of the metallic material and then performs a selective reactive ion etching process to remove the sidewall spacers, as shown in FIG. 6. NiPt, NiPtRe, NiPtTi, NiPtW, NiW, NiTi, NiPd alloy silicides usually have more Pt, W, Ti, Pd, Re segregated at the surface compared to the rest of the film, and therefore help to reduce the RIE damage during the processing shown in FIG. 6. Metal-rich silicide has more Ni and Pt at the surface because of the composition, therefore they enhance the protection against the RIE damage. Heavy elements (such as Pt, W, Ti, Pd, Re) at the silicide surface can withstand RIE damage and protect the surface.

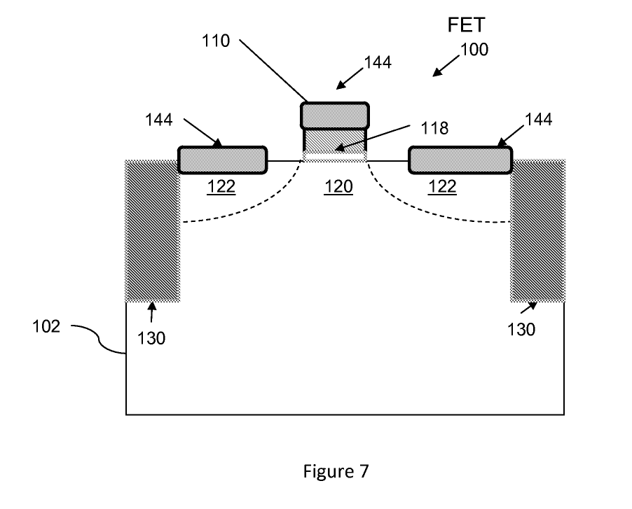

However, even with this increased RIE damage protection, the selected reactive ion etching process may produce some damage within the metal-rich silicide 142. Therefore, as shown in FIG. 7, the method performs a second rapid thermal annealing process at a higher (e.g., 25% higher, 50% higher, 100% higher, etc.) temperature than the first heating process shown in FIG. 5 to change the metal-rich silicide 142 into silicide 144 having a lower (e.g., 25% lower, 40% lower, 60% lower, etc.) metallic concentration than the metal-rich silicide 142. The silicide 144 formed does not suffer from such RIE damage because it is reformed from the excess metal in the metal-rich silicide 142 during the second annealing process shown in FIG. 7. This produces silicides 144 on the source and drain regions 122 and optionally silicide 144 on the gate conductor 110.

While only one transistor is illustrated in the drawings, those ordinarily skilled in the art would understand that many different types transistor could be simultaneously formed with the embodiments herein and the drawings are intended to show multiple different types of transistors; however, the drawings have been simplified to only show a single transistor for clarity and to allow the reader to more easily recognize the different features illustrated. This is not intended to limit the embodiments herein because, as would be understood by those ordinarily skilled in the art, the embodiment herein is applicable to structures that include many of each type of transistor.

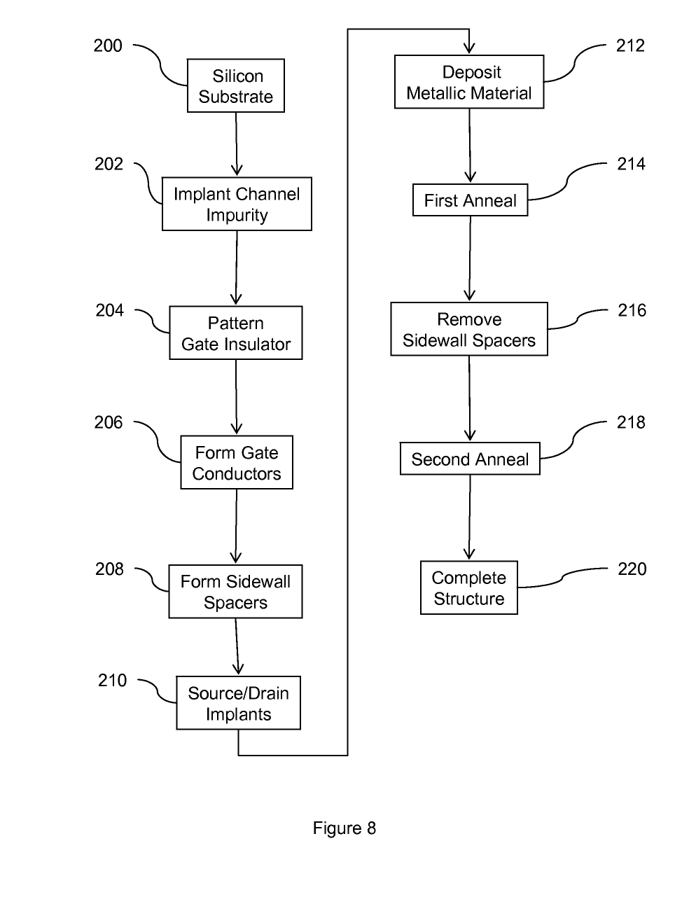

FIG. 8 illustrates a method embodiment herein that forms a transistor structure (in flowchart form). In item 200, the method provides a silicon substrate and, in item 202, implants an impurity into a region of the substrate to form at least one semiconductor channel region within the substrate. This embodiment then patterns an insulator on the substrate to form at least one gate insulator adjacent the channel region in item 204, and patterns a polysilicon conductor on the insulator to form at least one gate conductor on the insulator in item 206. As discussed above, the gate insulator is between the gate conductor and the channel region. The method forms insulating sidewall spacers on sidewalls of the gate conductor in item 208, and implants an additional impurity into the substrate around the gate conductor and the sidewalls to form conductive source and drain regions within the substrate adjacent the channel region in item 210.

This method similarly deposits a metallic material over the substrate, the gate conductor, and the sidewalls in item 212, and performs a first rapid thermal annealing process to change the metallic material into a metal-rich silicide at locations where the metallic material contacts silicon in item 214. The method performs a selective reactive ion etching process to remove the sidewall spacers in item 216. The selected reactive ion etching (RIE) process in item 216 may produce some damage within the metal-rich silicide. However, the method also performs a second rapid thermal annealing process in item 218 to change the metal-rich silicide into silicide having a lower metallic concentration than the metal-rich silicide. Again, this silicide that is formed does not suffer from such RIE damage because it is reformed from the excess metal in the metal-rich silicide during the second annealing process 218. In item 220, the additional caps, insulator layers, contacts, etc. are formed, as would be understood by those ordinarily skilled in the art, to complete and package the above structure. The embodiments herein are implemented at a low cost and simply, and do not require new processes or tools.

The resulting integrated circuit chip can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should be understood that the corresponding structures, materials, acts, and equivalents of all means or step plus function elements in the claims below are intended to include any structure, material, or act for performing the function in combination with other claimed elements as specifically claimed. Additionally, it should be understood that the above-description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated. Well-known components and processing techniques are omitted in the above-description so as to not unnecessarily obscure the embodiments of the invention.

Finally, it should also be understood that the terminology used in the above-description is for the purpose of describing particular embodiments only and is not intended to be limiting of the invention. For example, as used herein, the singular forms “a”, “an” and “the” are intended to include the plural forms as well, unless the context clearly indicates otherwise. Furthermore, as used herein, the terms “comprises”, “comprising,” and/or “incorporating” when used in this specification, specify the presence of stated features, integers, steps, operations, elements, and/or components, but do not preclude the presence or addition of one or more other features, integers, steps, operations, elements, components, and/or groups thereof.

What is claimed is:

1. A method of forming a structure comprising:
depositing a metallic material over a silicon material having sidewall spacers;
performing a first heating process to change said metallic material into a metal-rich silicide at locations where said metallic material contacts silicon;
removing said sidewall spacers; and
performing a second heating process to change said metal-rich silicide into silicide having a lower metallic concentration than said metal-rich silicide.

2. The method according to claim 1, wherein said second heating process is performed at a higher temperature than said first heating process.

3. The method according to claim 1, further comprising performing a pre-cleaning operation before depositing said metallic material.

4. The method according to claim 1, further comprising removing un-reacted portions of said metallic material before removing said sidewall spacers.

5. The method according to claim 1, wherein said metallic material comprises the metallic alloy.

6. The method according to claim 5, wherein said metallic alloy comprises at least two of nickel, lead, tungsten, titanium, rhenium, and palladium.

7. A method of forming a transistor structure comprising:
forming at least one channel region within a silicon substrate;
forming at least one gate insulator on said substrate adjacent said channel region;
forming at least one gate conductor on said gate insulator to position said gate conductor such that said gate insulator is between said gate conductor and said channel region;
forming insulating sidewall spacers on sidewalls of said gate conductor;
forming source and drain regions within said substrate adjacent said channel region;
depositing a metallic material over said substrate, said gate conductor, and said sidewalls;
performing a first heating process to change said metallic material into a metal-rich silicide at locations where said metallic material contacts silicon;
removing said sidewall spacers; and
performing a second heating process to change said metal-rich silicide into silicide having a lower metallic concentration than said metal-rich silicide.

8. The method according to claim 7, wherein said second heating process is performed at a higher temperature than said first heating process.

9. The method according to claim 7, further comprising performing a pre-cleaning operation before depositing said metallic material.

10. The method according to claim 7, further comprising removing un-reacted portions of said metallic material before removing said sidewall spacers.

11. The method according to claim 7, wherein said metallic material comprises the metallic alloy.

12. The method according to claim 11, wherein said metallic alloy comprises at least two of nickel, lead, tungsten, titanium, rhenium, and palladium.

13. A method of forming a transistor structure comprising:
providing a silicon substrate;
implanting an impurity into a region of said substrate to form at least one channel region within said substrate;
patterning an insulator on said substrate to form at least one gate insulator adjacent said channel region;
patterning a conductor on said insulator to form at least one gate conductor on said insulator and to position said gate conductor such that said gate insulator is between said gate conductor and said channel region;
forming insulating sidewall spacers on sidewalls of said gate conductor;
implanting additional impurity into said substrate around said gate conductor and said sidewalls to form source and drain regions within said substrate adjacent said channel region;
depositing a metallic material over said substrate, said gate conductor, and said sidewalls;
performing a first heating process to change said metallic material into a metal-rich silicide at locations where said metallic material contacts silicon;
removing said sidewall spacers; and
performing a second heating process to change said metal-rich silicide into silicide having a lower metallic concentration than said metal-rich silicide.

14. The method according to claim 13, wherein said second heating process is performed at a higher temperature than said first heating process.

15. The method according to claim 13, further comprising performing a pre-cleaning operation before depositing said metallic material.

16. The method according to claim 13, further comprising removing un-reacted portions of said metallic material before removing said sidewall spacers.

17. The method according to claim 13, wherein said metallic material comprises the metallic alloy.

18. The method according to claim 13, wherein said metallic alloy comprises at least two of nickel, lead, tungsten, titanium, rhenium, and palladium.
